(19) United States
(12) Patent Application Publication
(10) Pub. No.: US 2023/0040627 A1
(43) Pub. Date: Feb. 9, 2023

(54) SELECTION GATE STRUCTURE AND FABRICATION METHOD FOR 3D MEMORY

(71) Applicant: Applied Materials, Inc., Santa Clara, CA (US)

(72) Inventors: Chang Seok Kang, Santa Clara, CA (US); Tomohiko Kitajima, San Jose, CA (US); Gill Yong Lee, San Jose, CA (US); Sung-Kwan Kang, Santa Clara, CA (US)

(73) Assignee: Applied Materials, Inc., Santa Clara, CA (US)

(21) Appl. No.: 17/879,097

(22) Filed: Aug. 2, 2022

Related U.S. Application Data
(60) Provisional application No. 63/228,765, filed on Aug. 3, 2021.

(51) Int. Cl. H01L 27/11524; G11C 16/04; H01L 27/11556; H01L 27/1157; H01L 27/11582

(52) U.S. Cl. CPC H01L 27/11524; G11C 16/0483; H01L 27/11556; H01L 27/1157; H01L 27/11582

(57) ABSTRACT

Described is a semiconductor memory device and methods of manufacture. The semiconductor memory device comprises a memory array comprising at least one select-gate-for-drain (SGD) transistor and at least one memory transistor, the memory array having at least one strapping region and at least one strapping contact, the strapping contact connecting a select-gate-for-drain (SGD) transistor to a strapping line.

### CROSS-REFERENCE TO RELATED APPLICATIONS

This application claims priority to U.S. Provisional Application No. 63/228,765, filed Aug. 3, 2021, the entire disclosure of which is hereby incorporated by reference herein.

### TECHNICAL FIELD

Embodiments of the present disclosure pertain to the field of electronic devices and methods and apparatus for manufacturing electronic devices. More particularly, embodiments of the disclosure provide select-gate-for-drain (SGD) transistors and methods for forming.

### BACKGROUND

Semiconductor technology has advanced at a rapid pace and device dimensions have shrunk with advancing technology to provide faster processing and storage per unit space. In NAND devices, the string current needs to be high enough to obtain sufficient current to differentiate ON and OFF cells. The string current is dependent on the carrier mobility which is enhanced by enlarging the grain size of the silicon channel.

Current 3D-NAND devices, which have a memory stack comprising alternating layers of an oxide material and a nitride material, have multiple memory holes between two slits. For the access to each cell by a word line and bit line, the memory holes between slits needs to be divided by select gate at drain (SGD) cut. For example, Toshiba 96L stacked 3D NAND with 8 memory holes and one dummy hole has one SGD cut separates the holes into two groups. In order to reduce the array size of 3D-NAND, the number of holes between slits (nHole) needs to be increased. If nHole increases more than 8 holes, there needs to be more than one SGD cut for the same technology. The holes under the same bit line level should be separately accessible by a combination of bit line (BL) and word line (WL). In other words, holes under same bit line are selected independently by a select gate for drain (SGD) and bit line. For this purpose, SGDs between slits should be separated by an SGD-cut. When the number of holes between slits (nHole) is small, e.g., ≤8, one SGD-cut separate select gate for drains (SGDs). However, when the number of holes between slits (nHole) is large, e.g., ≥12), SGD-cut needs to be added for every four holes.

Accordingly, there is a need in the art for 3D-NAND devices and methods of fabricating 3D-NAND devices having a select gate for drain (SGD) cut.

### SUMMARY

One or more embodiments of the disclosure are directed to a semiconductor memory device. In one or more embodiments, a semiconductor memory device comprises: a memory array comprising at least one select-gate-for-drain (SGD) transistor and at least one memory transistor, the memory array having at least one strapping region and at least one strapping contact, the strapping contact connecting a select-gate-for-drain (SGD) transistor to a strapping line.

Other embodiments of the disclosure are directed to a semiconductor memory device. In one or more embodiments, a semiconductor memory device comprises: a memory stack on a substrate, the memory stack comprising alternating layers of word line and dielectric material; a plurality of memory transistors extending through the memory stack; a filled slit extending through the memory stack and adjacent to the plurality of memory transistors; and a plurality of select-gate-for-drain (SGD) transistors in a top portion of the memory stack, wherein at least one of the plurality of select-gate-for-drain (SGD) transistors is electrically connected to a strapping line.

Additional embodiments of the disclosure are directed to a method of forming a semiconductor device. In one or more embodiments, a method of forming a semiconductor device comprises: forming a plurality of memory holes extending through a memory stack, the memory stack comprising alternating layers of a first layer and a second layer on a substrate; depositing transistor layers in the plurality of memory holes to form a plurality of memory strings; forming a bit line pad on a top surface of each of the plurality of memory strings; forming a select-gate-for-drain (SGD) transistor on a top portion of the memory stack; forming a slit extending through the memory stack to the substrate; removing the first layer to form an opening in the memory stack; depositing a dielectric material in the opening; recessing the second layer to form a recessed region; depositing a low resistivity material in the recessed region; filling the slit to form a filled slit; forming a select-gate-for-drain contact; and forming a strapping line on a top surface of the memory stack, the strapping line contacting the select-gate-for drain contact.

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of forming a memory device according to embodiments described herein;

FIG. 2 illustrates a cross-sectional view of an electronic device with a memory stack according to one or more embodiments;

FIG. 3 illustrates a cross-sectional view of an electronic device after forming a staircase pattern of the memory stack according to one or more embodiments;

FIG. 4 illustrates a cross-sectional view of an electronic device according to one or more embodiments;

FIG. 5A illustrates a cross-sectional view of an electronic device according to one or more embodiments;

FIG. 5B illustrates an expanded view of region 132 according to one or more embodiments;

FIG. 6A illustrates a cross-sectional view of an electronic device according to one or more embodiments;

FIG. 6B illustrates an expanded view of region 132 according to one or more embodiments;

FIG. 7A illustrates a cross-sectional view of an electronic device according to one or more embodiments;

FIG. 7B illustrates an expanded view of region 132 according to one or more embodiments;

FIG. 8 illustrates a cross-sectional view of an electronic device according to one or more embodiments;

FIG. 9 illustrates a cross-sectional view of an electronic device according to one or more embodiments;

FIG. 10 illustrates a cross-sectional view of an electronic device according to one or more embodiments;

FIG. 11 illustrates a cross-sectional view of an electronic device according to one or more embodiments;

FIG. 12A illustrates a cross-sectional view of an electronic device according to one or more embodiments;

FIG. 12B illustrates an expanded view of region 132 according to one or more embodiments;

FIG. 13A illustrates a cross-sectional view of an electronic device according to one or more embodiments;

FIG. 13B illustrates an expanded view of region 132 according to one or more embodiments;

FIG. 14A illustrates a cross-sectional view of an electronic device according to one or more embodiments;

FIG. 14B illustrates an expanded view of region 132 according to one or more embodiments;

FIG. 15A illustrates a cross-sectional view of an electronic device according to one or more embodiments;

FIG. 15B illustrates an expanded view of region 132 according to one or more embodiments;

FIG. 16 illustrates a cross-sectional view of an electronic device according to one or more embodiments;

FIG. 17 illustrates a cross-sectional view of an electronic device according to one or more embodiments;

FIG. 18A illustrates a cross-sectional view of an electronic device according to one or more embodiments;

FIG. 18B illustrates a cross-sectional view of an electronic device according to one or more embodiments;

FIG. 19A illustrates a cross-sectional view of an electronic device according to one or more embodiments;

FIG. 19B illustrates a cross-sectional view of an electronic device according to one or more embodiments;

FIG. 20A illustrates a cross-sectional view of an electronic device according to one or more embodiments;

FIG. 20B illustrates a cross-sectional view of an electronic device according to one or more embodiments;

FIG. 21A illustrates a cross-sectional view of an electronic device according to one or more embodiments;

FIG. 21 B illustrates a cross-sectional view of an electronic device according to one or more embodiments;

FIG. 21C illustrates a cross-sectional view of an electronic device according to one or more embodiments; and

FIG. 22 illustrates a cluster tool according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been descried in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used in this specification and the appended claims, the terms “precursor”, “reactant”, “reactive gas” and the like are used interchangeably to refer to any gaseous species that can react with the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

In existing 3D NAND devices based on a memory stack of alternating layers of an oxide material and a nitride material, a non-replacement word line process using silicon (Si) based material as word line is an alternative way to avoid process difficulties of word line replacement process. One of the disadvantages in poly-silicon based word line, however, is the high word line resistance compared to tungsten (W) in the oxide/nitride (ON) mold. To reduce poly-silicon word line resistance, word line edge silicidation has been used. The select-gate-for drain (SGD), however, which is not exposed to slit cannot use a word line capped with low resistance material. The entire performance of the cell is affected by the resistance (R) of the SGD gate, the capacitance (C) connected with the SGD gate, and the time of delay (RC delay) of SGD. Thus, reduction in RC delay of SGD is a critical issue in Si-based word line schemes. Accordingly, one or more embodiments advantageously provides a structure and an integration method to improve RC-delay of SGDs by adopting strapping lines. In one or more embodiments, at least one SGD is strapped with a lower resistance metal line in more than one position.

One or more embodiments provide structures and methods for fabricating a memory array comprising at least one select-gate-for-drain (SGD) transistor and at least one memory transistor. The memory array has at least one strapping region and at least one strapping contact. The strapping contact connects a select-gate-for-drain (SGD) transistor to a strapping line. The device and fabrication method of one or more embodiments advantageously have an SGD with a reduced RC delay. In one or more embodiments, the at least one strapping region comprises a first plurality of memory holes that is less dense than a second plurality of memory holes in a non-strapping region.

In one or more embodiments, metal deposition and other processes can be carried out in an isolated environment (e.g., a cluster process tool). Accordingly, some embodiments of the disclosure provide integrated tool systems with related process modules to implement the methods.

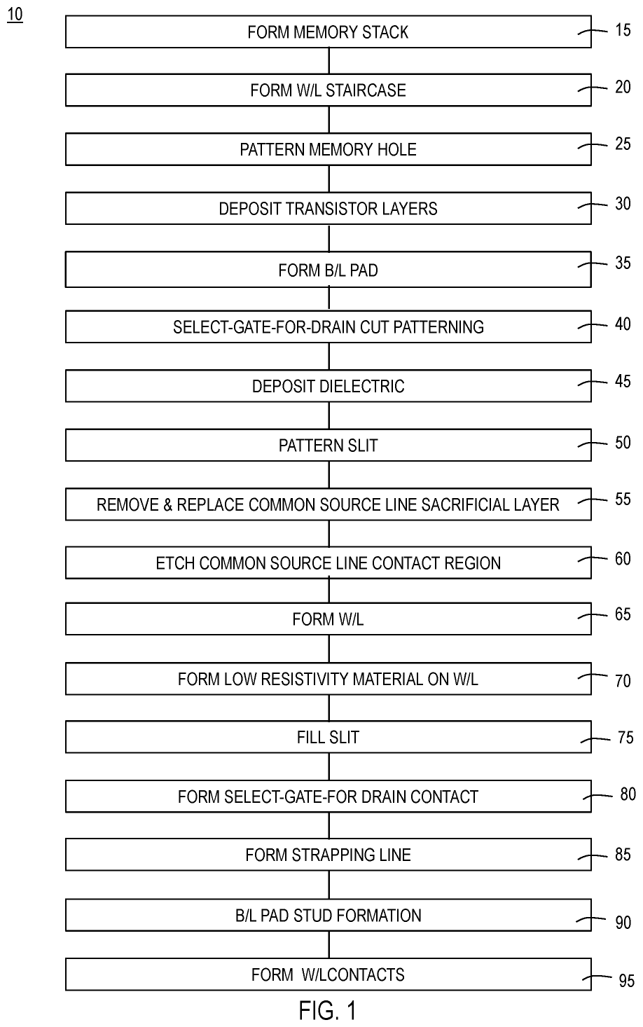

FIG. 1 illustrates a flowchart for an exemplary method 10 for forming a memory device. The skilled artisan will recognize that the method 10 can include any or all of the processes illustrated. Additionally, the order of the individual processes can be varied for some portions. The method 10 can start at any of the enumerated processes without deviating from the disclosure.

With reference to FIG. 1, at operation 15, a memory stack is formed. At operation 20, a word line staircase is formed in the memory stack. At operation 25, a memory hole is patterned through the memory stack. At operation 30, transistor layers are deposited in the memory hole. At operation 35, the bit line pad is formed. At operation 40, a select-gate-for-drain (SGD) cut is patterned. At operation 45, a dielectric is deposited in the opening formed by the select-gate-for-drain cut. At operation 50, the device is slit patterned. At operation 55, the sacrificial layer of the common source line is removed and replaced. At operation, 60, the common source line is etched to form a common source line contact region. At operation 65, the word line is formed. At operation 70, a low resistivity material is formed on the word line. At operation 75, the slit is filled with a dielectric material. At operation 80, the select-gate-for-drain contact is formed. At operation 85, the strapping line is formed. At operation 90, the bit line pad studs are formed. At operation 95, word line contacts are formed.

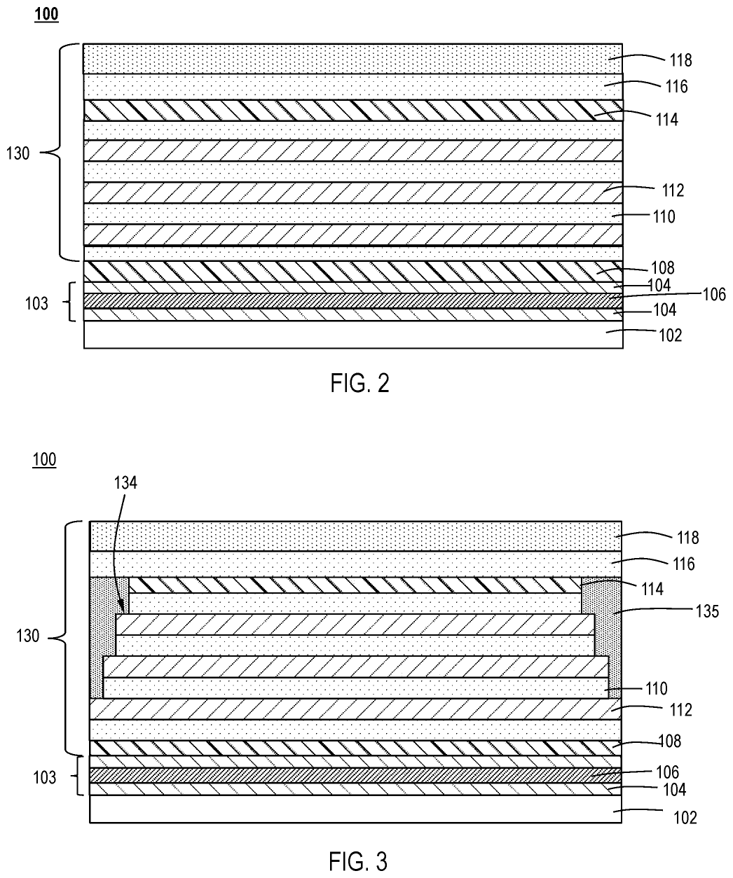

FIGS. 2-21C illustrate a portion of a memory device 100 following the process flow illustrated for the method 10 in FIG. 1.

FIG. 2 illustrates an initial or starting memory stack of an electronic device 100 in accordance with one or more embodiments of the disclosure. In some embodiments, the electronic device 100 shown in FIG. 2 is formed on the bare substrate 102 in layers, as illustrated. The electronic device of FIG. 2 is made up of a substrate 102, a common source line 103, and a memory stack 130.

The substrate 102 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

In one or more embodiments, a common source line 103 is on the substrate 102. The common source line 103 may also be referred to as the semiconductor layers. The common source line 103 can be formed by any suitable technique known to the skilled artisan and can be made from any suitable material including, but not limited to, poly-silicon (poly-Si). In some embodiments, the common source line 103 comprises several different conductive or a semiconductor material. For example, in one or more embodiments, as illustrated in FIG. 2, the common source line 103 comprises a poly-silicon layer 104 on the substrate 102, a sacrificial layer 106 on the polysilicon layer, and a second polysilicon layer 104 on the sacrificial layer 106.

In one or more embodiments, a sacrificial layer 106 may formed on the polysilicon layer 104 and can be made of any suitable material. The sacrificial layer 106 in some embodiments is removed and replaced in later processes. In some embodiments, the sacrificial layer 106 is not removed and remains within the memory device 100. In this case, the term “sacrificial” has an expanded meaning to include permanent layers and may be referred to as the conductive layer. In the illustrated embodiment, as described further below, the sacrificial layer 106 is removed in operation 70. In one or more embodiments, the sacrificial layer 106 comprises a material that can be removed selectively versus the neighboring polysilicon layer 104. In one or more embodiments, the sacrificial layer comprises a nitride material, e.g., silicon nitride (SiN), or an oxide material, e.g., silicon oxide (SiOₓ).

In one or more embodiments, an oxide layer 108 is formed on a top surface of the common source line 103. The oxide layer 108 may comprise any suitable material known to the skilled artisan. In one or more embodiments, the oxide layer 108 comprises silicon oxide (SiOₓ).

In one or more embodiments, a memory stack 130 is formed on the oxide layer 108 on the common source line 103. The memory stack 130 in the illustrated embodiment comprises a plurality of alternating first layers 110 and second layers 112. While the memory stack 130, illustrated in FIG. 2, has three pairs of alternating first layers 110 and second layers 112, one of skill in the art recognizes that this is merely for illustrative purposes only. The memory stack 130 may have any number of alternating first layers 110 and second layers 112. For example, in some embodiments, the memory stack 130 comprises 192 pairs of alternating first layers 110 and second layers 112. In other embodiments, the memory stack 130 comprises greater than 50 pairs of alternating first layers 110 and second layers 112, or greater than 100 pairs of alternating first layers 110 and second layers 112, or greater than 300 pairs of alternating first layers 110 and second layers 112.

In one or more embodiments, the second layers 112 are replacement layers. In one or more embodiments, the first layers 110 and the second layers 112 independently comprise a dielectric material. In one or more embodiments, the dielectric material may comprise any suitable dielectric material known to the skilled artisan. As used herein, the term “dielectric material” refers to an electrical insulator that can be polarized in an electric field. In some embodiments, the dielectric material comprises one or more of oxides, carbon doped oxides, porous silicon dioxide (SiO₂), silicon dioxide (SiO), silicon nitride (SiN), silicon dioxide/silicon nitride, carbides, oxycarbides, nitrides, oxynitrides, oxycarbonitrides, polymers, phosphosilicate glass, fluorosilicate (SiOF) glass, or organosilicate glass (SiOCH).

In one or more embodiments, the second layers 112 comprise a material that is etch selective relative to the first layers 110 so that the second layers 112 can be removed without substantially affecting the first layers 110. In one or more embodiments, the first layers 110 comprise silicon (Si) layers and the second layers 112 comprise silicon germanium (SiGe) layers.

The individual alternating layers may be formed to any suitable thickness. In some embodiments, the thickness of each second layer 112 is approximately equal. In one or more embodiments, each second layer 112 has a second layer thickness. In some embodiments, the thickness of each first layer 110 is approximately equal. As used in this regard, thicknesses which are approximately equal are within +/− 5% of each other. In some embodiments, a silicon layer (not shown) is formed between the second layers 112 and first layers 110. The thickness of the silicon layer may be relatively thin as compared to the thickness of a layer of second layers 112 or first layers 110. In one or more embodiments, the first layers 110 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments the first layer 110 has a thickness in the range of from about 0.5 to about 40 nm. In one or more embodiments, the second layers 112 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments, the second layer 112 has a thickness in the range of from about 0.5 to about 40 nm.

In one or more embodiments first layers 110 and second layers 112 are deposited by chemical vapor deposition (CVD) or physical vapor deposition (PVD). In some embodiments, the first layers 110 and second layers 112 re deposited by plasma enhanced chemical vapor deposition (PE-CVD). The individual alternating layers may be formed to any suitable thickness. In some embodiments, the thickness of each second layer 112 is approximately equal. In one or more embodiments, each second layer 112 has a first second layer thickness. In some embodiments, the thickness of each first layer 110 is approximately equal. As used in this regard, thicknesses which are approximately equal are within +/− 5% of each other. In one or more embodiments, the first layers 110 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm. In one or more embodiments, the second layers 112 have a thickness in a range of from about 0.5 nm to about 30 nm, including about 1 nm, about 3 nm, about 5 nm, about 7 nm, about 10 nm, about 12 nm, about 15 nm, about 17 nm, about 20 nm, about 22 nm, about 25 nm, about 27 nm, and about 30 nm.

In one or more embodiments, select-gate-for-drain material 116 is formed on a top surface of the memory stack 130. In one or more embodiments, the select-gate-for-drain gate material 116 is formed on a top surface of an oxide layer 114. In one or more embodiments, the select-gate-for-drain gate material 116 comprises one or more of poly-silicon or a metal. The metal may comprise any suitable metal known to the skilled artisan. In some embodiments, the metal is a refractory metal. In one or more embodiments, the metal may be selected from one or more of tungsten (W), molybdenum (Mo), ruthenium (Ru), iridium (Ir), tantalum (Ta), titanium (Ti), and osmium (Os).

In one or more embodiments, an oxide material 118 is formed on a top surface of the select-gate-for-drain material 116. The oxide material 118 may comprise any suitable material known to the skilled artisan. In some embodiments, the oxide material comprises silicon oxide (SiOₓ).

Referring to FIG. 3, at operation 20 of method 10, a staircase formation is created. In one or more embodiments, the staircase formation exposes a top surface 134 of the second layers 112. The top surface 134 can be used to provide space for word line contacts to be formed, as described below. A suitable fill material 135 can be deposited to occupy the space outside the staircase formation. A suitable fill material 135, as will be understood by the skilled artisan, can be any material that prevents electrical shorting between adjacent word lines. A staircase formation with each word line having a smaller width (illustrated from left-to-right in the figures) than the word line below. Use of relative terms like “above” and “below” should not be taken as limiting the scope of the disclosure to a physical orientation in space.

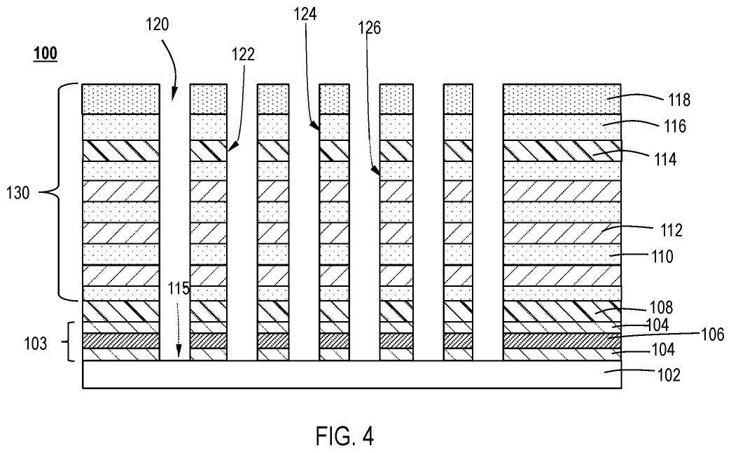

It is to be noted that for ease of illustration, the staircase formation is not shown in FIGS. 4-21, but, as recognized by one of skill in the art, the staircase formation is present.

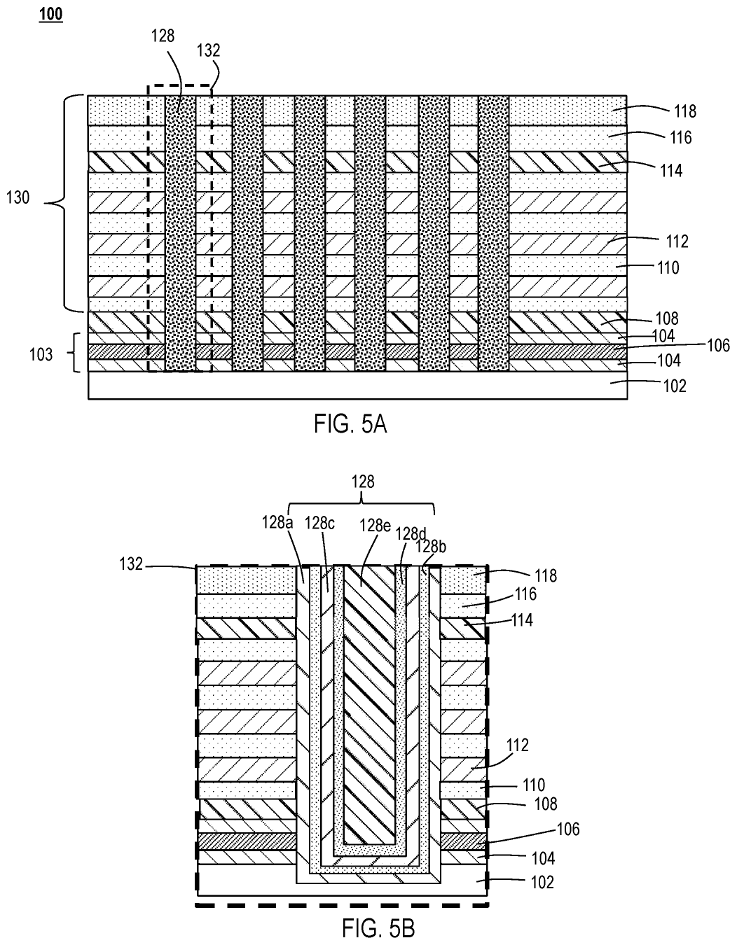

FIGS. 4-5B illustrate the formation of a memory string through the memory stack 130. With reference to FIG. 4, at operation 25 a memory hole channel 120 is opened/patterned through the memory stack 130. In some embodiments, opening the memory hole channel 120 comprises etching through the oxide layer 118, the select-gate-for-drain material 116, the oxide layer 114, the memory stack 130, the common source line 103, and into substrate 102. The memory hole channel 120 has sidewalls that extend through the memory stack 130 exposing surfaces 126 of the second layers 112 and surfaces 124 of the first layers 110.

The select-gate-for-drain gate material 116 has surfaces 136 exposed as sidewalls of the memory hole channel 120. The memory hole channel 120 extends a distance into the substrate 102 so that sidewall surfaces 136, 124, 126, and bottom 115 of the memory hole channel 120 are formed within the substrate 102. The bottom 115 of the memory hole channel 120 can be formed at any point within the thickness of the substrate 102. In some embodiments, the memory hole channel 120 extends a thickness into the substrate 102 in the range of from about 10% to about 90%, or in the range of from about 20% to about 80%, or in the range of from about 30% to about 70%, or in the range of from about 40% to about 60% of the thickness of the substrate 102. In some embodiments, the memory hole channel 120 extends a distance into the substrate 102 by greater than or equal to 10 nm. In some embodiments, the memory hole channel 120 extends from a top surface of the select-gate-for-drain (SGD) gate 116 and the oxide layer 118 through the memory stack to a bottom surface of the substrate.

FIG. 5A shows operation 30 in which the transistor layers 128 are formed in the memory hole channel 120. The transistor layers 128 can be formed by any suitable technique known to the skilled artisan. In some embodiments, the transistor layers are formed by a conformal deposition process. In some embodiments, the transistor layers are formed by one or more of atomic layer deposition or chemical vapor deposition.

In one or more embodiments, the deposition of the transistor layers 128 is substantially conformal. As used herein, a layer which is “substantially conformal” refers to a layer where the thickness is about the same throughout (e.g., on the top, middle and bottom of sidewalls and on the bottom of the memory hole channel 120). A layer which is substantially conformal varies in thickness by less than or equal to about 5%, 2%, 1% or 0.5%. The transistor layers 128 in the memory hole may comprise one or more of an aluminum oxide (AlO) layer, a blocking oxide layer, a trap layer, a tunnel oxide layer, and a channel layer.

Referring to FIG. 5B, which is an expanded view of region 132 of FIG. 5A, in one or more embodiments, the transistor layers 128 comprises an aluminum oxide layer 128a, a blocking oxide layer 128b, a nitride trap layer 128c, a tunnel oxide layer 128d, and a channel material 128e in the memory hole channel 120. In one or more embodiments, the channel material 128e comprises poly-silicon. In one or more embodiments, the aluminum oxide layer 128a is deposited in the memory hole channel 120 on the sidewalls of the memory hole channel 120.

The transistor layers 128 can have any suitable thickness depending on, for example, the dimensions of the memory hole channel 120. In some embodiments, the transistor layers 128 have a thickness in the range of from about 0.5 nm to about 50 nm, or in the range of from about 0.75 nm to about 35 nm, or in the range of from about 1 nm to about 20 nm.

In one or more embodiments, the transistor layers 128 comprise a memory transistor, and the transistor layers 128 independently comprise one or more transistor layers selected from aluminum oxide (AlO), a blocking oxide, a trap material, a tunnel oxide, and a channel layer/channel material.

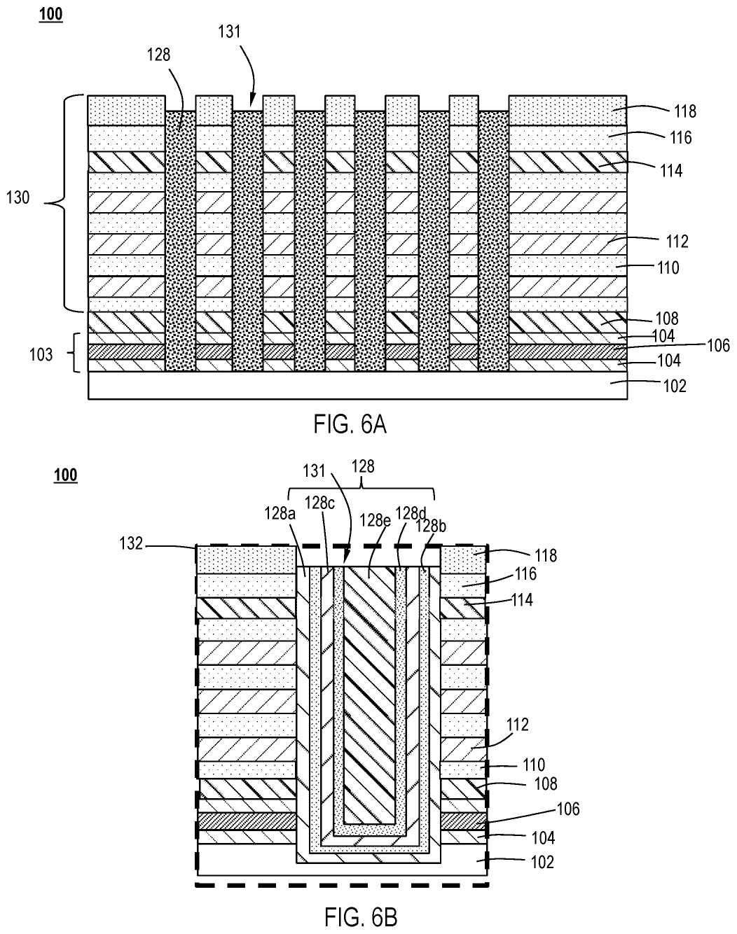

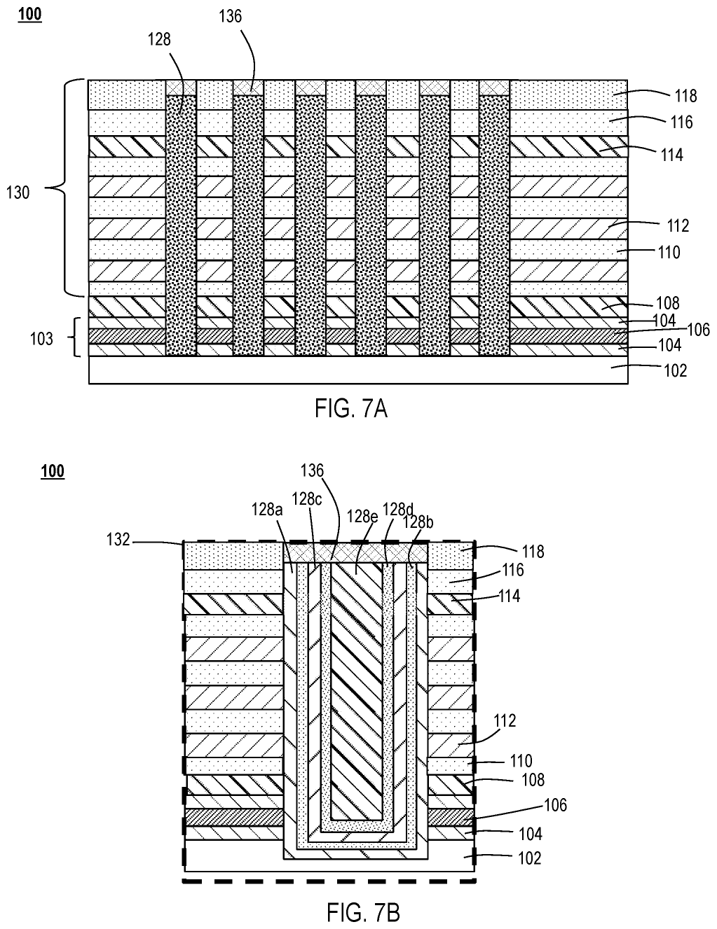

FIGS. 6A-7B show operation 35 of method 10 where a bit line pad 136 is formed on the top surface of the transistor layers 128 and in the oxide layer 118. In one or more embodiments, the bit line pad 136 is formed on a drain side of the select-gate-for-drain (SGD) transistor. The bit line pad 136 can be any suitable material known to the skilled artisan including, but not limited to, poly-silicon. Referring to FIGS. 6A and 6B, the transistor layers 128 are etched back to form a recess 131. As illustrated in FIGS. 7A and 7B, the recess 131 is then filled with a bit line pad 136.

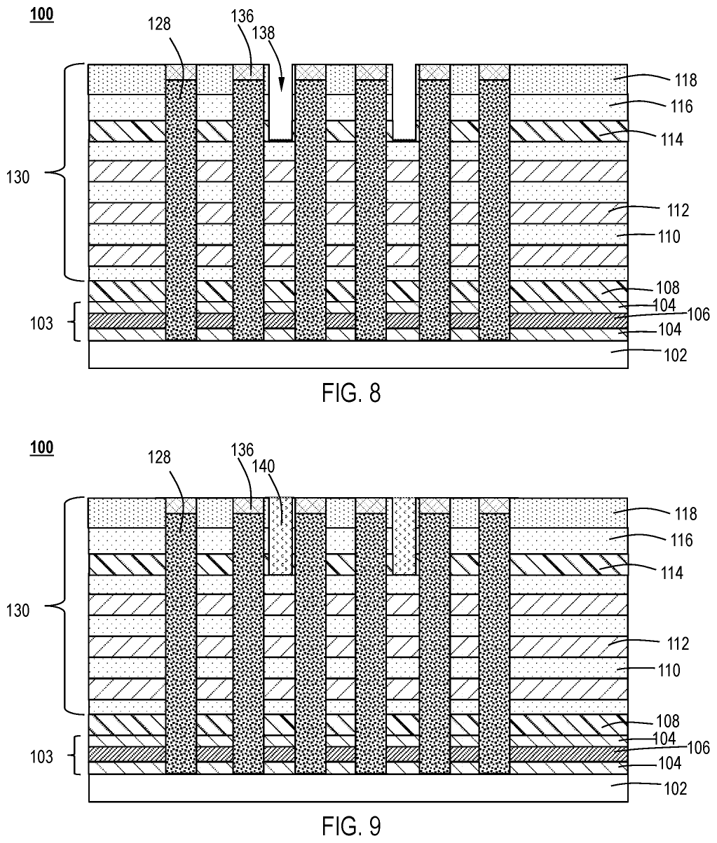

Referring to FIG. 8, at operation 40, selection gate is etched/cut into the memory stack forming an opening 138. In some embodiments, this may be referred to as patterning a select-gate-for-drain cut (SGD). The opening 138 extends from a top surface of the oxide layer 118 to a top surface of the oxide layer 114. The etching/patterning may be conducted by any suitable means known to the skilled artisan. In one or more embodiments, forming the opening comprises 138 a selection-gate-for-drain (SGD) separation etch.

Referring to FIG. 9, at operation 45, a selection-gate-for-drain (SGD) isolation is formed in the opening 138. In one or more embodiments, forming the selection-gate-for-drain (SGD) isolation comprises depositing a dielectric material 140 in the opening 138. The dielectric material 140 may be deposited by any suitable method known to the skilled artisan. In one or more embodiments, the dielectric material 140 is deposited by atomic layer deposition (ALD). The dielectric material 140 may comprise by any suitable dielectric material known to the skilled artisan. In one or more embodiments, the dielectric material 140 comprises one or more of silicon oxide (SiOₓ) or silicon oxynitride (SiON).

In some unillustrated embodiments, the dielectric material 140 may be deposited in the opening 138 and form an overburden on a top surface of the oxide layer 118. The overburden may then be removed by any suitable technique known to the skilled artisan. For example, in one or more embodiments, the overburden may be removed by chemical mechanical planarization (CMP).

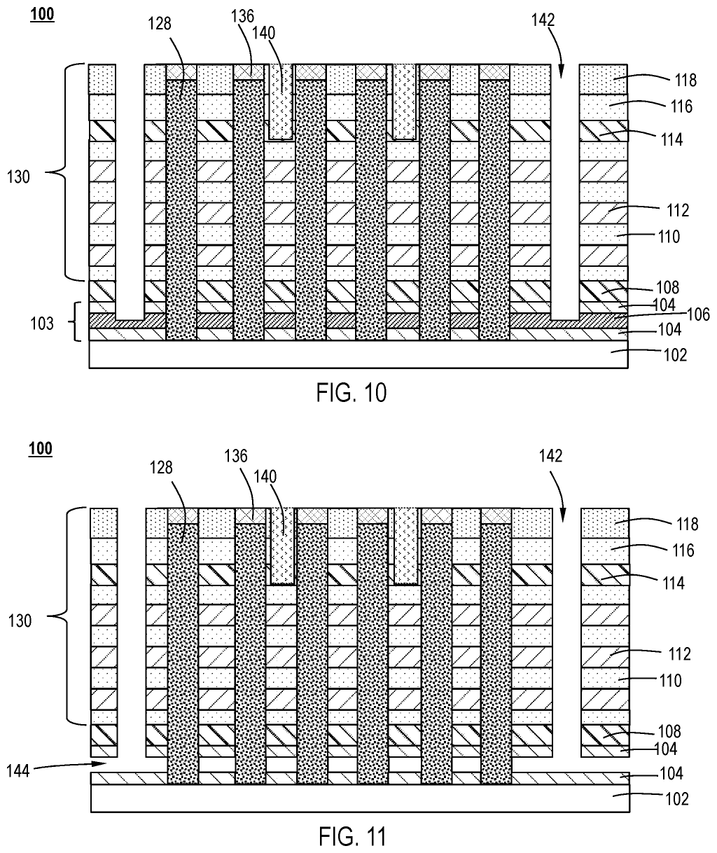

Referring to FIG. 10, at operation 50 of method 10, the memory stack 130 is slit patterned to form slit pattern openings 142 that extend from a top surface of the oxide layer 118 to the sacrificial layer 106 of the common source line 103.

FIG. 11 illustrates operation 55 of method 10 where the sacrificial layer 106 in the common source line 103 is removed to form opening 144. The sacrificial layer 106 can be removed by any suitable technique known to the skilled artisan including, but not limited to, selective etching, hot phosphoric acid, and the like.

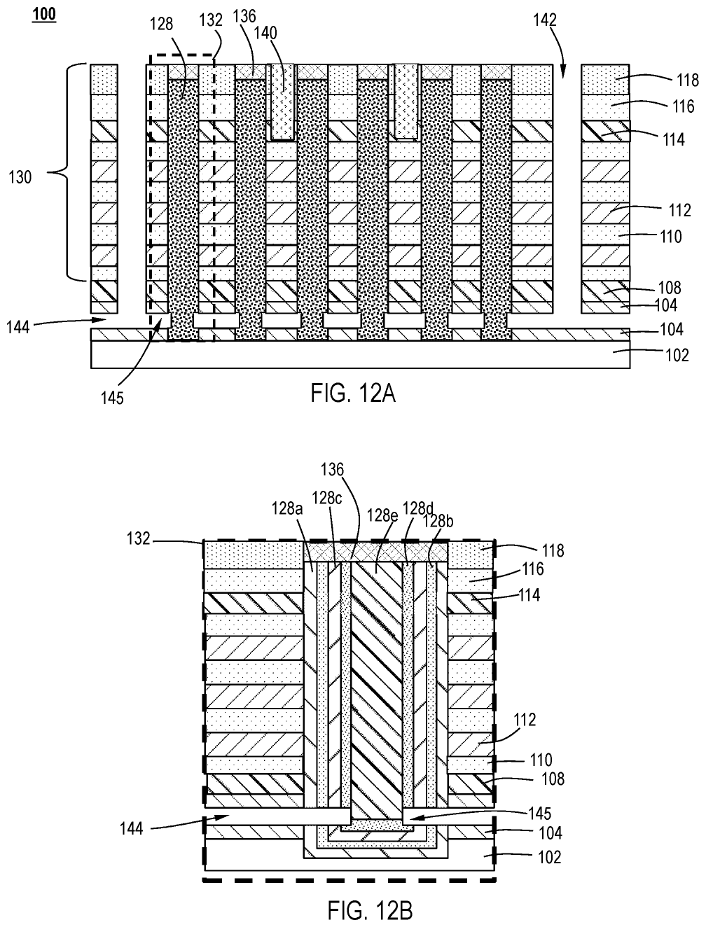

FIG. 12A and FIG. 12B, which is an expanded view of region 132 of FIG. 12A, show operation 60 of method 10, where the channel material 128e is exposed to form a common source line contact region 145. The channel material 128e is exposed by removing the aluminum oxide (A10) layer 128a, the blocking oxide layer 128b, the trap layer 128c, and the tunnel oxide layer 128d in the common source line contact region 145.

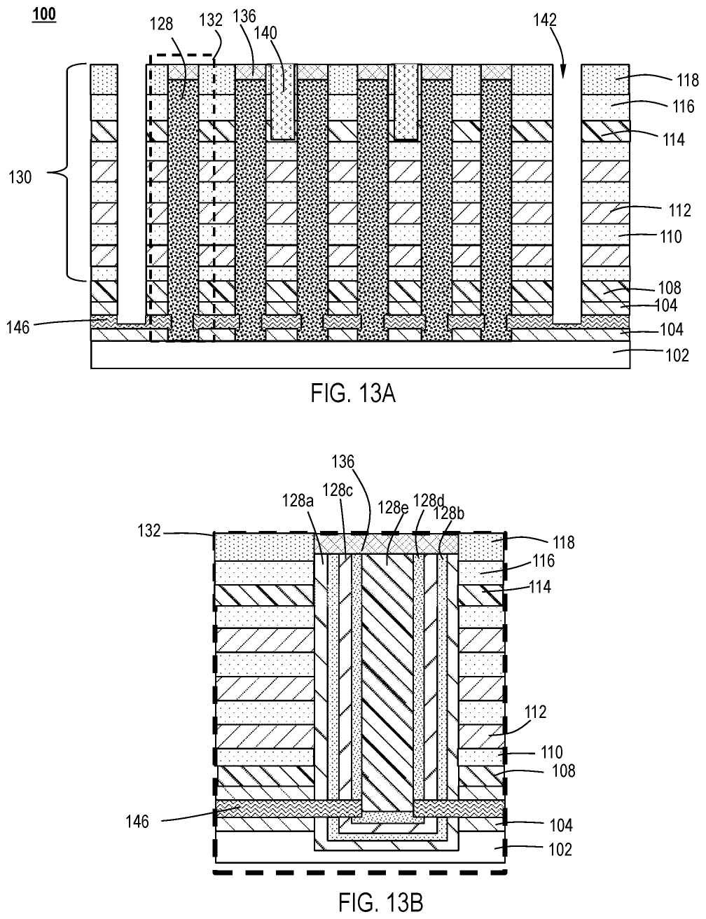

FIGS. 13A and 13B show operation 55 of method 10 where a poly-silicon layer 146 is deposited in opening 144, thus replacing the common source line sacrificial layer 106. The poly-silicon layer 146 may be doped or undoped.

Operation 65 Where the Word Line

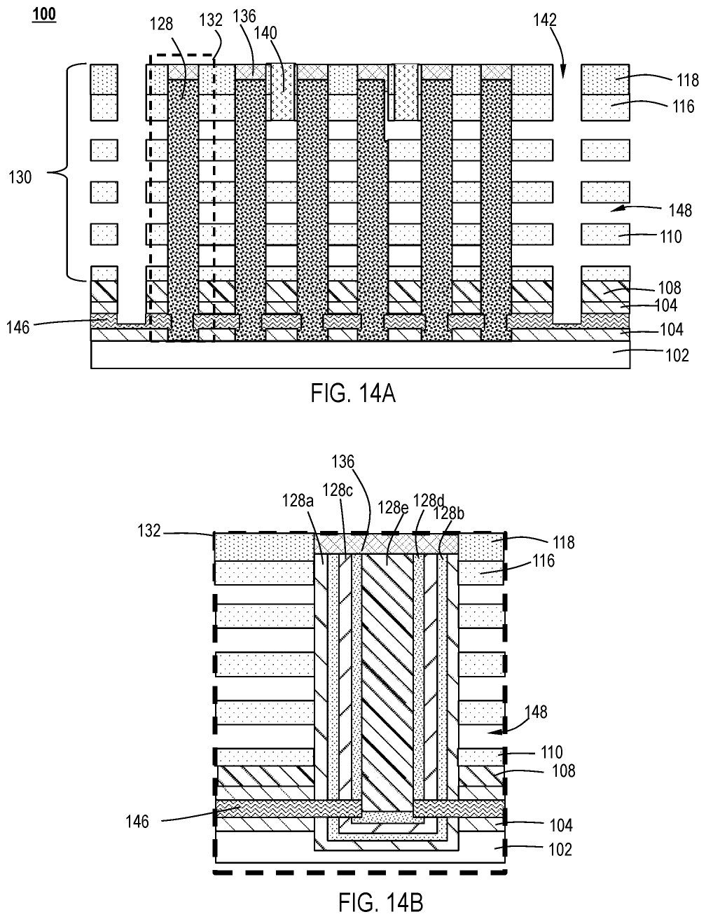

FIGS. 14A thru 15B illustrate operation 65 where the word lines are formed. Referring to FIGS. 14A and 14B, the second layers 112 are removed to form an opening 148. The second layers 112 may be removed by any suitable means known to the skilled artisan. In one or more embodiments, the second layers 112 are removed by selective etching, e.g., selective wet etching or selective dry etching. Removal of the second layers 112 forms opening 148.

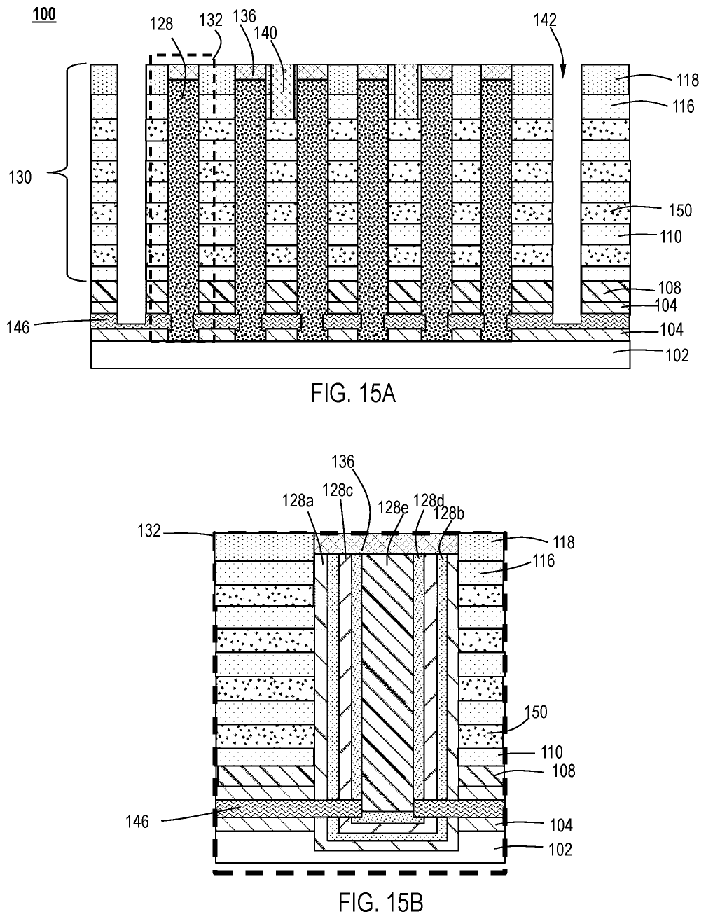

FIGS. 15A and 15B, show deposition of a conformal dielectric layer 150 in opening 148. FIG. 15B is an enlarged view of area 132 of FIG. 15A. The dielectric layer 150 may comprise any suitable dielectric material known to the skilled artisan. In one or more embodiments, the dielectric layer 150 is a low-K dielectric that includes, but is not limited to, materials such as, e.g., silicon dioxide, silicon oxide, carbon doped oxide (“CDO”), e.g., carbon doped silicon dioxide, porous silicon dioxide (SiO₂), silicon nitride (SiN), or any combination thereof. While the term “silicon oxide” may be used to describe the dielectric layer 136, the skilled artisan will recognize that the disclosure is not restricted to a particular stoichiometry. For example, the terms “silicon oxide” and “silicon dioxide” may both be used to describe a material having silicon and oxygen atoms in any suitable stoichiometric ratio. The same is true for the other materials listed in this disclosure, e.g., silicon nitride, silicon oxynitride, aluminum oxide, zirconium oxide, and the like. In specific embodiments, the dielectric layer 150 comprises silicon oxide.

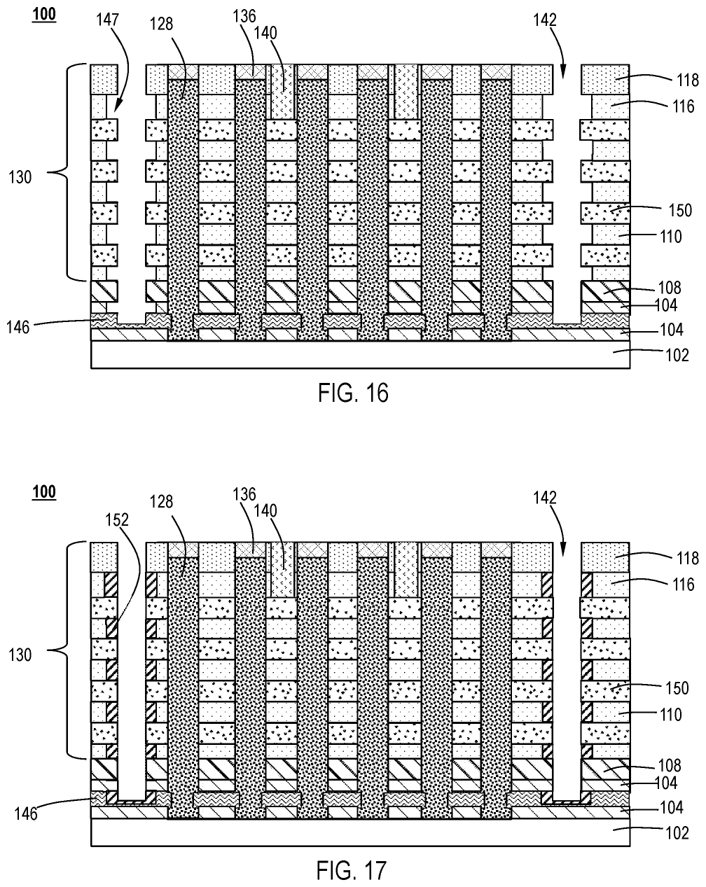

At operation 70, a low resistance word line is advantageously formed. In one or more embodiments, it may be advantageous for the word line to comprise low resistivity materials. In some embodiments, the low resistivity material has a resistivity in a range of from 5 μΩcm to 100 μΩcm. In some embodiments, as illustrated in FIGS. 16 and 17, low resistivity materials may be formed by recessing the word line and selectively growing the low resistivity materials in the recessed portion of the word line. In other embodiments, low resistivity materials may be formed by depositing a metal layer and silicidating the metal in the word line region and in the common source line region.

Referring to FIG. 16, the word line first material layer 110 is recessed to form a recessed region 147. With reference to FIG. 17, a low resistivity material 152 is conformally deposited in slit 142 into the recessed region 147. The low resistivity material 152 may comprise any suitable material known to the skilled artisan. In one or more embodiments, the low resistivity material 152 comprises one or more of tungsten (W), ruthenium (Ru), aluminum (Al), iridium (Ir), tantalum (Ta), titanium (Ti), platinum (Pt), molybdenum (Mo), nickel (Ni), or a silicide thereof. Thus, in one or more embodiments, the low resistivity material 152 comprises one or more of tungsten (W), ruthenium (Ru), iridium (Ir), tantalum (Ta), titanium (Ti), platinum (Pt), molybdenum (Mo), nickel (Ni), tungsten silicide (WSi), ruthenium silicide (RuSi), aluminum silicide (AlSi), iridium silicide (IrSi), tantalum silicide (TaSi), titanium silicide (TiSi), platinum silicide (PtSi), molybdenum silicide (MoSi), and nickel silicide (NiSi). Accordingly, in one or more embodiments, the memory transistor comprises a first material 110 and a second material 152, the first material 110 having a higher resistance than the second material 152. Thus, the poly-silicon word line comprises a first material and a second material, the first material 110 having a higher resistance than the second material 152, the second material 152 adjacent to the slit region (i.e., the filled slit 142).

In one or more embodiments, the slit 142 is filled with an insulator material. The insulator material may be any suitable material known to the skilled artisan. In one or more embodiments, the insulator material is selected from one or more of silicon oxide, silicon nitride, and silicon oxynitride.

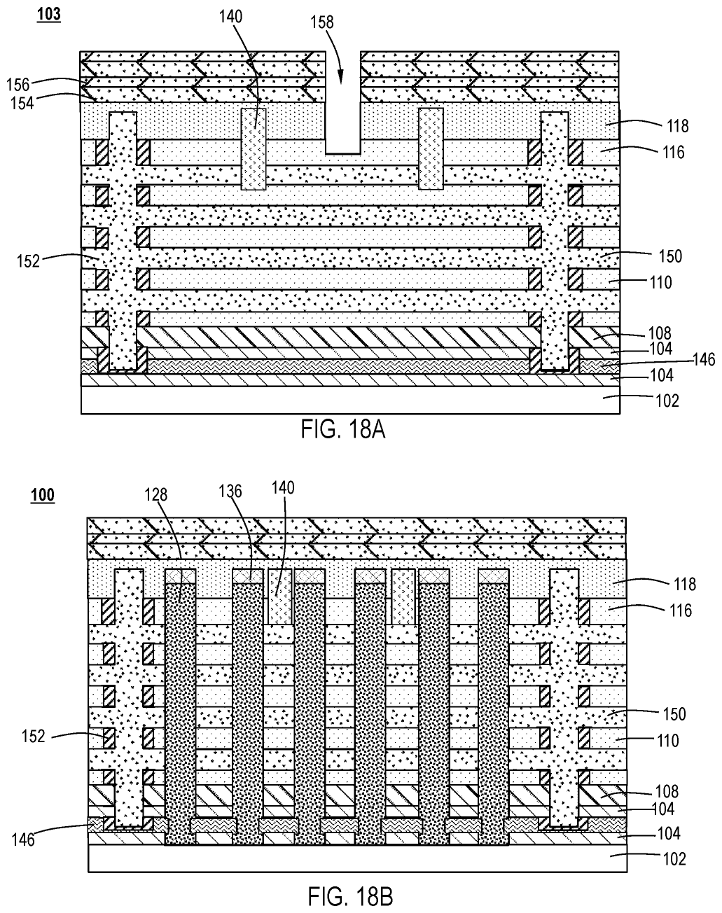

FIGS. 18A thru 21C show cross-section views 103, 100, 105, and 107 for both normal array region and SGD strapping region to show SGD strapping line clearly.

With reference to FIG. 18A and FIG. 18B, a contact to connect SGD with a scrapping line is formed. An SGD contact hole 158 is patterned, formed in the region where memory holes are missing. A scrapping contact line can be formed along with other contact in non-array region.

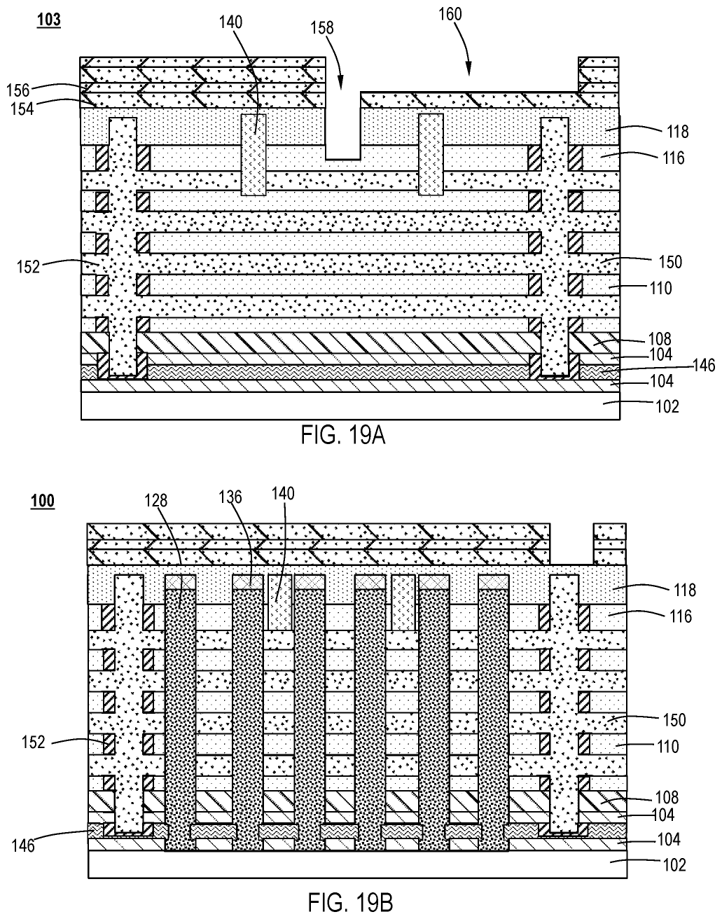

Referring to FIGS. 19A and 19B, a strapping line region 160 is formed. The scrapping line region 160 can be formed along with other metallization in non-array region.

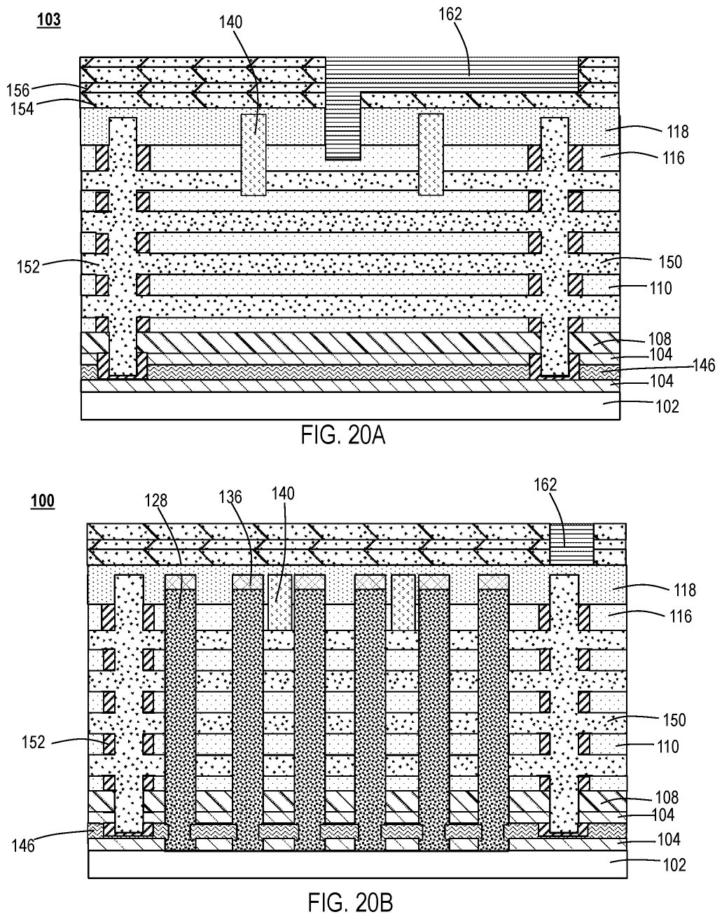

Referring to FIGS. 20A and 20B, the strapping line region 160 is filled with one or more of a barrier metal and a metal to form the strapping line 162. The barrier metal may comprise any suitable material known to the skilled artisan. In one or more embodiments, the barrier metal comprises one or more of titanium (Ti), titanium nitride (TiN), tantalum (Ta), and tantalum nitride (TaN). The metal may comprise any suitable metal known to the skilled artisan. In one or more embodiments, the metal comprises one or more of tungsten (W), aluminum (Al), copper (Cu), titanium (Ti), tantalum (Ta), ruthenium (Ru), and molybdenum (Mo). In specific embodiments, the strapping line 162 comprises tungsten (W).

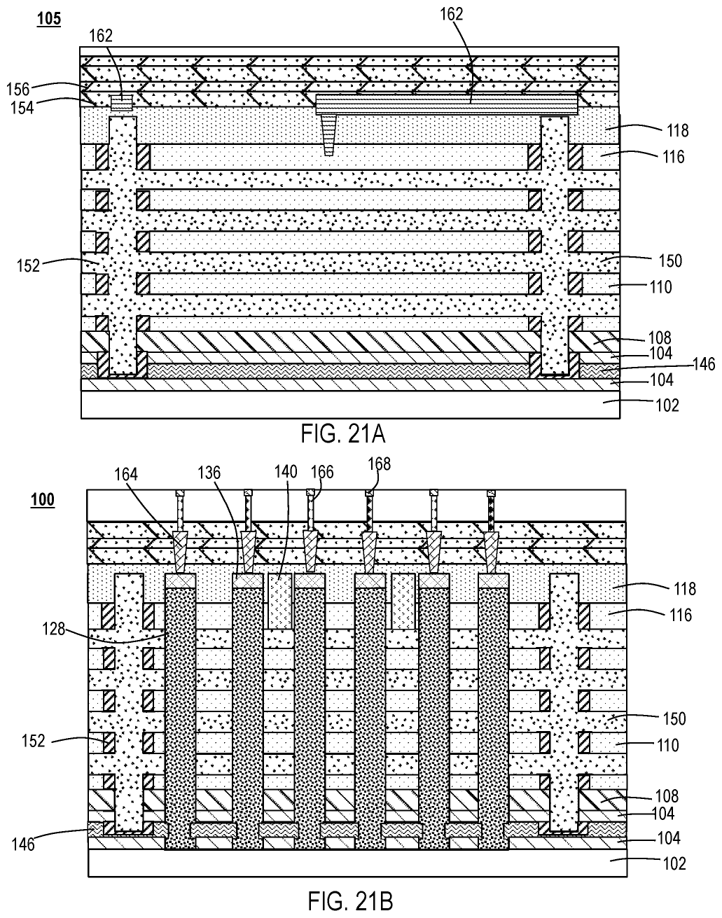

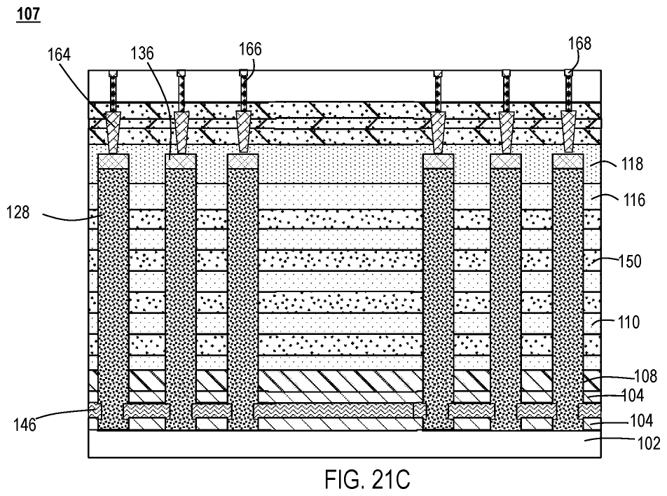

With reference to FIGS. 21A thru 21C, strapping contacts including the bit line 168, the bit line contact 166, and the bit line stud 164 are formed.

In other embodiments, a method of forming a semiconductor device is provided. The semiconductor device may have a three-dimensional vertical memory string including a select gate for drain (SGD) transistor. In one or more embodiments, the method of forming a semiconductor device comprises forming a plurality of memory holes extending through a memory stack. The memory stack comprises alternating layers of a first layer and a second layer on a substrate. Transistor layers are deposited in the plurality of memory holes to form a plurality of memory strings. A bit line pad is formed on a top surface of each of the plurality of memory strings. A select-gate-for-drain (SGD) transistor is then formed on a top portion of the memory stack. The memory stack is patterned to form a slit extending through the memory stack to the substrate. The first layer is removed to form an opening in the memory stack, and a dielectric material is deposited in the opening. The second layer is recessed to form a recessed region, and a low resistivity material is deposited in the recessed region. The slit is filled form a filled slit. A select-gate-for-drain contact is then formed, and a strapping line is formed on a top surface of the memory stack. The strapping line contacts the select-gate-for drain contact.

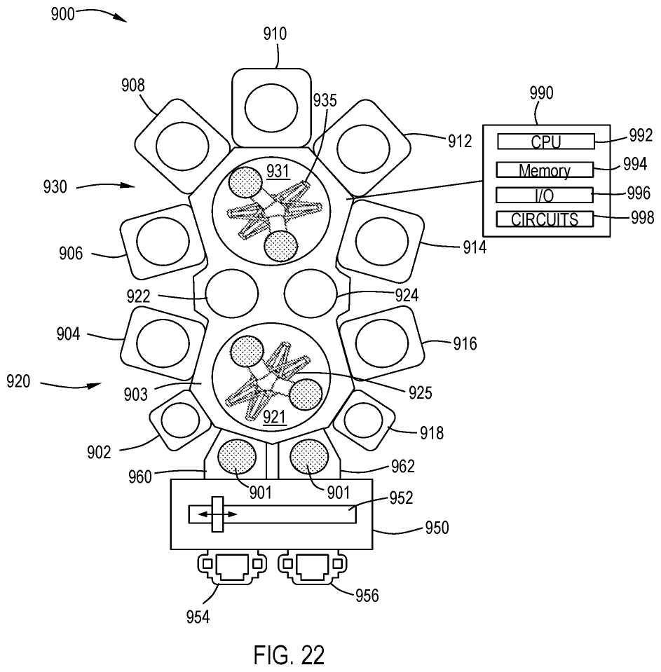

Additional embodiments of the disclosure are directed to processing tools 900 for the formation of the memory devices and methods described, as shown in FIG. 22.

The cluster tool 900 includes at least one central transfer station 921, 931 with a plurality of sides. A robot 925, 935 is positioned within the central transfer station 921, 931 and is configured to move a robot blade and a wafer to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber, annealing chamber, etching chamber, or a word line deposition chamber. The particular arrangement of process chambers and components can be varied depending on the cluster tool and should not be taken as limiting the scope of the disclosure.

In some embodiments, the cluster tool 900 includes a selection-gate-for-drain (SGD) patterning chamber. The selection-gate-for-drain (SGD) patterning chamber of some embodiments comprises one or more selective etching chamber.

In the embodiment shown in FIG. 22, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the cluster tool 900. In the embodiment shown, the loading chamber 954 and unloading chamber 956 are sized to hold a wafer cassette with a plurality of wafers positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In some embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a selection-gate-for-drain (SGD) patterning chamber; and a controller connected to the central transfer station and the plurality of process stations, the controller configured to activate the robot to move the wafer between process stations, and to control a process occurring in each of the process stations.

One or more embodiments provide a non-transitory computer readable medium including instructions, that, when executed by a controller of a processing chamber, causes the processing chamber to perform the operations of: form a plurality of memory holes extending through a memory stack, the memory stack comprising alternating layers of a first layer and a second layer on a substrate; deposit transistor layers in the plurality of memory holes to form a plurality of memory strings; form a bit line pad on a top surface of each of the plurality of memory strings; form a select-gate-for-drain (SGD) transistor on a top portion of the memory stack; form a slit extending through the memory stack to the substrate; remove the first layer to form an opening in the memory stack; deposit a dielectric material in the opening; recess the second layer to form a recessed region; deposit a low resistivity material in the recessed region; fill the slit to form a filled slit; form a select-gate-for-drain contact; and form a strapping line on a top surface of the memory stack, the strapping line contacting the select-gate-for drain contact.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A semiconductor memory device comprising:
a memory array comprising at least one select-gate-for-drain (SGD) transistor and at least one memory transistor, the memory array having at least one strapping region and at least one strapping contact, the at least one strapping contact connecting a select-gate-for-drain (SGD) transistor to a strapping line.

2. The semiconductor memory device of claim 1, wherein the at least one strapping region comprises a first plurality of memory holes that is less dense than a second plurality of memory holes in a non-strapping region.

3. The semiconductor memory device of claim 1, wherein the select-gate-for-drain (SGD) transistor comprises a poly-silicon word line.

4. The semiconductor memory device of claim 1, wherein the memory transistor comprises a first material and a second material, the first material has a higher resistance than the second material.

5. The semiconductor memory device of claim 4, wherein the second material is adjacent to a slit region of the memory array.

6. The semiconductor memory device of claim 1, wherein the strapping line comprises one or more of tungsten (W), aluminum (Al), copper (Cu), titanium (Ti), tantalum (Ta), molybdenum (Mo), and ruthenium (Ru).

7. A semiconductor memory device comprising:
a memory stack on a substrate, the memory stack comprising alternating layers of word line and dielectric material;
a plurality of memory transistors extending through the memory stack;
a filled slit extending through the memory stack and adjacent to the plurality of memory transistors; and
a plurality of select-gate-for-drain (SGD) transistors in a top portion of the memory stack, wherein at least one of the plurality of select-gate-for-drain (SGD) transistors is electrically connected to a strapping line.

8. The semiconductor memory device of claim 7, wherein each of the plurality of select-gate-for-drain (SGD) transistors comprises a poly-silicon word line.

9. The semiconductor memory device of claim 7, wherein the poly-silicon word line comprises a first material and a second material, the first material having a higher resistance than the second material, the second material adjacent to the filled slit.

10. The semiconductor memory device of claim 9, wherein the second material comprises one or more of tungsten (W), molybdenum (Mo), titanium (Ti), aluminum (Al), ruthenium (Ru), tantalum (Ta), or a silicide thereof.

11. The semiconductor memory device of claim 7, wherein each of the plurality of memory transistors comprises one or more transistor layers selected from aluminum oxide (ALO), a blocking oxide, a trap material, a tunnel oxide, and a channel material.

12. The semiconductor memory device of claim 7, wherein the filled slit comprises an insulator material selected from one or more of silicon oxide, silicon nitride, and silicon oxynitride.

13. The semiconductor memory device of claim 7, wherein the substrate is a common source line, the common source line comprising a sacrificial layer, an oxide layer, and a poly-silicon layer.

14. The semiconductor memory device of claim 7, wherein the strapping line comprises one or more of tungsten (W), aluminum (Al), copper (Cu), titanium (Ti), tantalum (Ta), molybdenum (Mo), and ruthenium (Ru).

15. A method of forming a semiconductor device, the method comprising:
forming a plurality of memory holes extending through a memory stack, the memory stack comprising alternating layers of a first layer and a second layer on a substrate;
depositing transistor layers in the plurality of memory holes to form a plurality of memory strings;
forming a bit line pad on a top surface of each of the plurality of memory strings;
forming a select-gate-for-drain (SGD) transistor on a top portion of the memory stack;
forming a slit extending through the memory stack to the substrate;
removing the first layer to form an opening in the memory stack;
depositing a dielectric material in the opening;
recessing the second layer to form a recessed region;
depositing a low resistivity material in the recessed region;
filling the slit to form a filled slit;
forming a select-gate-for-drain contact; and
forming a strapping line on a top surface of the memory stack, the strapping line contacting the select-gate-for-drain contact.

16. The method of claim 15, wherein the transistor layers comprise one or more of an aluminum oxide (AlO) layer, a blocking oxide layer, a trap layer, a tunnel oxide layer, and a channel layer.

17. The method of claim 15, wherein the low resistivity material comprises one or more of tungsten (W), ruthenium (Ru), aluminum (Al), iridium (Ir), tantalum (Ta), titanium (Ti), platinum (Pt), molybdenum (Mo), nickel (Ni), or a silicide thereof.

18. The method of claim 15, wherein the filled slit comprises an insulator material selected from one or more of silicon oxide, silicon nitride, and silicon oxynitride.

19. The method of claim 15, wherein the substrate is a common source line, the common source line comprising a sacrificial layer, an oxide layer, and a poly-silicon layer.

20. The method of claim 15, wherein the strapping line comprises one or more of tungsten (W), aluminum (Al), copper (Cu), titanium (Ti), tantalum (Ta), molybdenum (Mo), and ruthenium (Ru).
